(19) United States
(12) Patent Application Publication
(10) Pub. No.: US 2005/0161767 A1
(43) Pub. Date: Jul. 28, 2005

(54) Semiconductor device and manufacturing method thereof

(75) Inventor: Shigeyuki Sugihara, Ibi-gun (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/019,105

(22) Filed: Dec. 22, 2004

(30) Foreign Application Priority Data
Dec. 22, 2003 (JP) 2003-425379

(51) Int. Cl. H01L 21/8238; H01L 21/20; H01L 29/00

(52) U.S. Cl. 257/536; 257/537; 438/382; 438/383

(57) ABSTRACT

Junction leakage in a diffused resistor having a silicide structure is prevented. A titanium layer is formed by sputtering titanium over an entire surface of a semiconductor substrate. A P⁺-type diffusion layer makes contact with the titanium layer through an opening. Subsequent heat treatment changes portions of the titanium layer, which are in contact with the P⁺-type diffusion layer, into silicide to form a titanium silicide layer on a surface of the P⁺-type diffusion layer. Then the rest of the titanium layer, which is not changed into silicide, is removed by wet-etching.

### CROSS-REFERENCE OF THE INVENTION

This invention is based on Japanese Patent Application No. 2003-425379, the content of which is incorporated herein by reference in its entirety.

### BACKGROUND OF THE INVENTION

1. Field of the Invention

This invention relates to a semiconductor device and its manufacturing method, specifically to a diffused resistor with a silicide structure and its manufacturing method.

2. Description of the Related Art

Silicide structures have been used in diffused resistors to reduce a contact resistance between a metal wiring and a diffusion layer so that a semiconductor device including the diffused resistor can be fabricated with finer design rules and operate at a higher speed.

FIG. 7 shows a cross-sectional view of such a diffused resistor. Device isolation regions 22a and 22b are formed on an N-type silicon substrate 21 to surround an active region by LOCOS (Local Oxidation of Silicon) or STI (Shallow Trench Isolation). A P⁺-type diffusion layer 24 is formed in the active region. Titanium silicide (TiSix) layers 27a and 27b are formed only in openings in a silicide block layer 25. Metal wiring layers 29a and 29b are formed after depositing an insulation film 28 and making contact holes in the insulation film 28 above the titanium silicide layers 27a and 27b. As a result, a diffused resistor including the P⁺-type diffusion layer 24 is connected between the metal wiring layer 29a and the metal wiring layer 29b.

FIG. 8 shows a cross-sectional view of another diffused resistor having the silicide structure. The diffused resistor has a withstand voltage as high as about 10 V, and is called a medium voltage diffused resistor. Device isolation regions 32a and 32b are formed on an N-type silicon substrate 31 to surround an active region by LOCOS or STI. A P⁻-type diffusion layer 33 is formed in the active region. A P⁺-type diffusion layer 34 shallower than the P⁻-type diffusion layer 33 is formed in the P⁻-type diffusion layer 33 a predetermined distance away from the device isolation regions 32a and 32b. Titanium silicide (TiSix) layers 37a and 37b are formed only in openings in a silicide block layer 35, similar to the diffused resistor shown in FIG. 7. Metal wiring layers 39a and 39b are formed after depositing an insulation film 38 and making contact holes in the insulation film 38 above the titanium silicide layers 37a and 37b. As a result, a diffused resistor including the P⁺-type diffusion layer 34 is connected between the metal wiring layer 39a and the metal wiring layer 39b. The medium voltage diffused resistor can realize a higher withstand voltage than the diffused resistor shown in FIG. 7, since an electric field induced by a voltage of about 10 V applied to the P⁺-type diffusion layer 34 is relaxed by the P⁻-type diffusion layer 33 formed between the P⁺-type diffusion layer 34 and the N-type silicon substrate 31.

P-type impurities are not properly injected into the P⁻-type diffusion layer 33 around boundaries between the P⁻-type diffusion layer 33 and each of the device isolation regions 32a and 32b, depending on the shape of the boundaries. Therefore, the P⁺-type diffusion layer 34 is formed in the P⁻-type diffusion layer 33 the predetermined distance away from the device isolation regions 32a and 32b in order to complement the withstand voltage reduced around the boundaries between the P⁻-type diffusion layer 33 and each of the device isolation regions 32a and 32b.

Since the P⁺-type diffusion layer 34 is located away from the device isolation regions 32a and 32b in the diffused resistor shown in FIG. 8, the P⁻-type diffusion layer 33 is exposed on the surface of the N-type silicon substrate 31. When titanium silicide is formed on the surface of the active region with a silicide block layer 35 covering only a portion of the surface of the P⁺-type diffusion layer 34 used as the resistor, the silicide layers 37a and 37b are formed on the P⁻-type diffusion layer 33 also. Since titanium absorbs P-type impurities (boron, for example) in the P⁻-type diffusion layer 33 during silicide reaction, a junction depth of the diffusion layer is reduced to cause junction leakage.

### SUMMARY OF THE INVENTION

This invention is directed to solve the problem addressed above, and offers a medium voltage diffused resistor having a silicide structure and being free of junction leakage.

In a diffused resistor according to this invention, a metal silicide layer is formed only on a high impurity concentration diffusion layer and not formed on a low impurity concentration diffusion layer.

### BRIEF DESCRIPTION OF THE DRAWINGS

FIGS. 1A, 1B and 1C are cross-sectional views showing a manufacturing method of a semiconductor device according to a first embodiment of this invention.

FIGS. 2A, 2B and 2C are cross-sectional views showing the manufacturing method of the semiconductor device according to the first embodiment of this invention.

FIG. 3 is a cross-sectional view showing the manufacturing method of the semiconductor device according to the first embodiment of this invention.

FIG. 4 is a plan view showing the semiconductor device according to the first embodiment of this invention.

FIGS. 5A-5D are cross-sectional views showing a manufacturing method of a semiconductor device according to a second embodiment of this invention.

FIG. 6 is a cross-sectional view showing a semiconductor device according to a third embodiment of this invention.

FIG. 7 is a cross-sectional view showing a semiconductor device according to a conventional art.

FIG. 8 is a cross-sectional view showing a semiconductor device according to another conventional art.

### DETAILED DESCRIPTION OF THE INVENTION

Next, semiconductor devices and their manufacturing method according to the embodiments of this invention will be explained referring to the figures hereinafter.

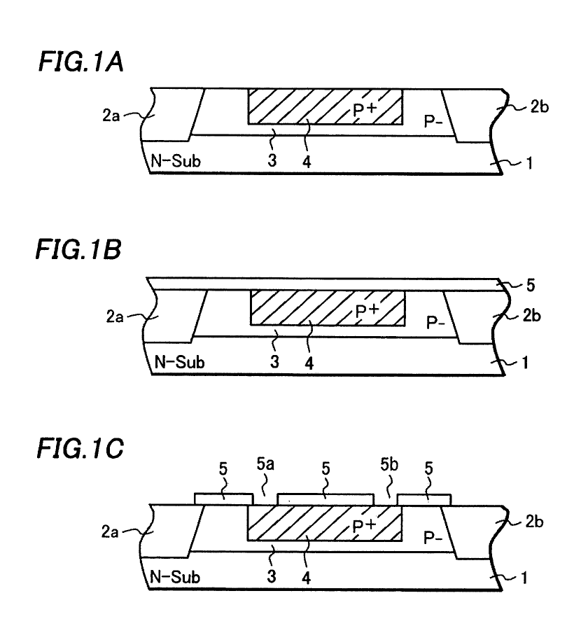

A first embodiment of this invention will be explained referring to FIGS. 1A-4. FIGS. 1A-3 are cross-sectional views showing a manufacturing method of a semiconductor device according to the first embodiment, and FIG. 4 is a plan view of the semiconductor device.

Device isolation regions 2a and 2b are formed on an N-type silicon substrate 1 to surround an active region, as shown in FIG. 1A. The device isolation regions 2a and 2b are made by LOCOS or STI process. A P⁻-type diffusion layer 3 is formed in the active region. A P⁺-type diffusion layer 4 shallower than the P⁻-type diffusion layer 3 is formed in the P⁻-type diffusion layer 3. Specifically, a low dose of P-type impurity ions such as boron is implanted into a surface of the active region in the N-type silicon substrate 1, and then thermal diffusion is performed. An impurity concentration in the P⁻-type diffusion layer 3 is about 1×10¹⁷/cm³, for example. However, the embodiment is not limited to this concentration. A high dose of P-type impurity ions such as boron is selectively implanted into a surface of a region in the N-type silicon substrate 1 to form a P⁺-type diffusion layer 4, the region being a predetermined distance away from the device isolation regions 2a and 2b. As a result, the P⁻-type diffusion layer 3 is exposed on the surface of the N-type silicon substrate 1 between the P⁺-type diffusion layer 4 and each of the device isolation regions 2a and 2b.

Next, a silicide block layer 5 made of a silicon oxide film is deposited over the entire surface of the silicon substrate 1, as shown in FIG. 1B. Openings 5a and 5b are formed in the silicide block layer 5 on the P⁺-type diffusion layer 4 by selectively etching the silicide block layer 5, as shown in FIG. 1C. Note that the silicide block layer 5 is left over the P⁻-type diffusion layer 3 in this process.

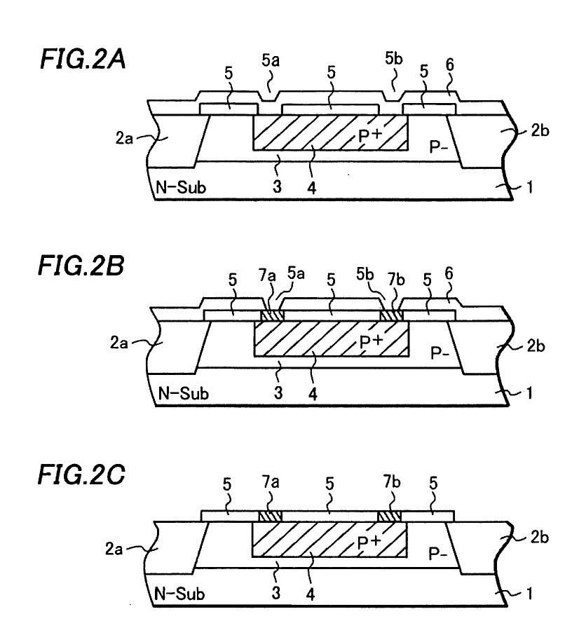

Next, a titanium layer 6 is formed by sputtering titanium (Ti) over the entire surface of the silicon substrate 1, as shown in FIG. 2A. Consequently, the P⁺-type diffusion layer 4 makes contact with the titanium layer 6 through the openings 5a and 5b. Subsequent heat treatment changes portions of the titanium layer 6, which are in contact with the P⁺-type diffusion layer 4, into silicide to form titanium silicide layers 7a and 7b on a surface of the P⁺-type diffusion layer 4, as shown in FIG. 2B. Then the rest of the titanium layer 6, which is not changed into silicide, is removed by wet-etching, as shown in FIG. 2C. Note that FIG. 2C is a cross-sectional view of a section X-X shown in a plan view of FIG. 4.

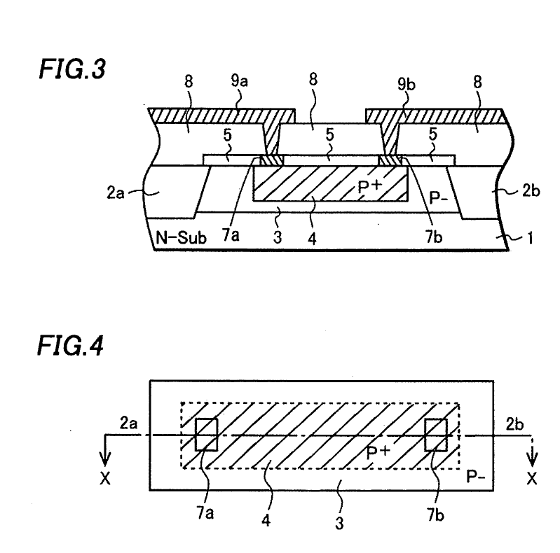

Next, an insulation film 8 is deposited over the entire surface of the silicon substrate 1, contact holes are formed in the insulation film 8 above the titanium silicide layers 7a and 7b, and metal wiring layers 9a and 9b are formed, as shown in FIG. 3.

As a result, a medium voltage diffused resistor having the P⁺-type diffusion layer 4 is connected between the metal wiring layer 9a and the metal wiring layer 9b.

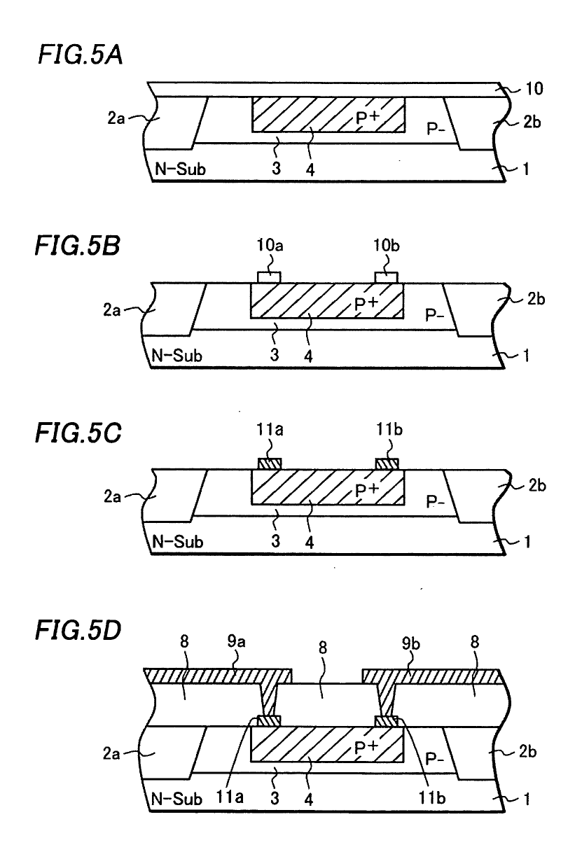

Next, a second embodiment of this invention will be explained, referring to FIGS. 5A-5D.

The same reference numerals are used in FIGS. 5A-5D as in FIGS. 1A-4 for the common components, and their detailed explanations are omitted. As shown in FIG. 5A, a titanium layer 10 is formed over the entire surface of the silicon substrate 1 in which the P⁺-type diffusion layer 4 has been formed through the process steps described in the explanation on FIG. 1A.

Next, the titanium layer 10 is selectively etched so that titanium layers 10a and 10b are left on the P⁺-type diffusion layer 4 while the rest being removed, as shown in FIG. 5B. After that, the titanium layers 10a and 10b are changed into silicide by heat treatment to form titanium silicide layers 11a and 11b, as shown in FIG. 5C.

Next, an insulation film 8 is deposited over the entire surface of the silicon substrate 1, contact holes are formed in the insulation film 8 above the titanium silicide layers 11a and 11b, and the metal wiring layers 9a and 9b are formed as shown in FIG. 5D.

As a result, a medium voltage diffused resistor having the P⁺-type diffusion layer 4 is connected between the metal wiring layer 9a and the metal wiring layer 9b.

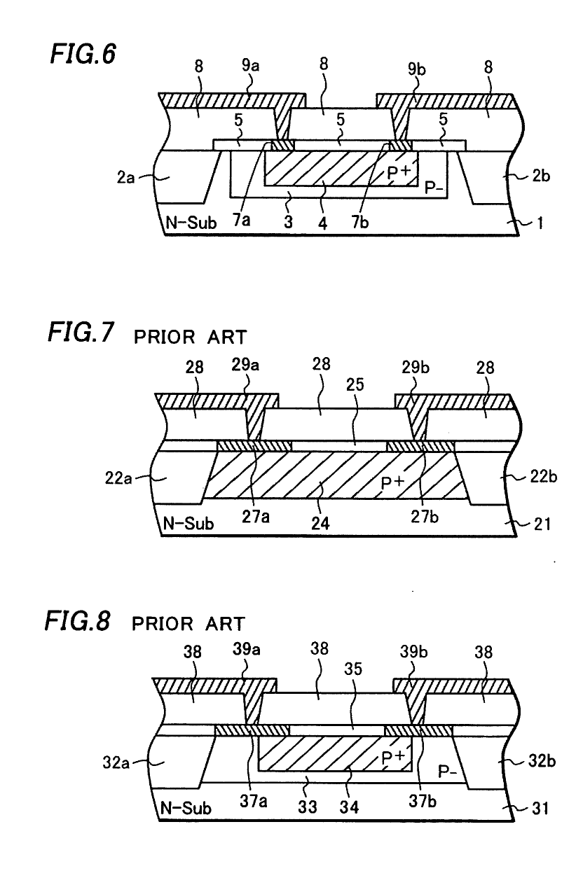

Note that a material other than the silicon oxide film, for example a silicon nitride film, may be used as the silicide block layer 7 in the first embodiment. Also, other refractory metals may be used instead of titanium in the first and the second embodiments. Moreover, the P⁻-type diffusion layer 3 is not necessarily in contact with the device isolation regions 2a and 2b in the first and the second embodiments. There may be the N-type silicon substrate 1 disposed between the P⁻-type diffusion layer 3 and each of the device isolation regions 2a and 2b, as in a third embodiment of this invention shown in FIG. 6. Furthermore, although the diffused resistor having the P⁺-type diffusion layer is used as an example in the explanations on the first and the second embodiments, this invention may be applied to a diffused resistor having an N⁺-type diffusion layer as well.

Junction leakage in the diffused resistor having the silicide structure can be prevented according to these embodiments. As a result, the medium voltage diffused resistor and small dimension MOS transistors having the silicide structure can be integrated into a single chip.

1. A semiconductor device comprising:
a semiconductor substrate of a first conductivity type;
a high impurity concentration diffusion layer of a second conductivity type formed in the semiconductor substrate, the second conductivity type being different from the first conductivity type;
a low impurity concentration diffusion layer of the second conductivity type formed in the semiconductor substrate and surrounding the high impurity concentration diffusion layer;
a silicide block layer formed on the low impurity concentration diffusion layer; and
a metal silicide layer formed on the high impurity concentration diffusion layer and not being in contact with the low impurity concentration diffusion layer.

2. A semiconductor device comprising:
a semiconductor substrate of a first conductivity type;
a high impurity concentration diffusion layer of a second conductivity type formed in the semiconductor substrate, the second conductivity type being different from the first conductivity type;
a low impurity concentration diffusion layer of the second conductivity type formed in the semiconductor substrate and surrounding the high impurity concentration diffusion layer; and
a metal silicide layer formed on the high impurity concentration diffusion layer and not being in contact with the low impurity concentration diffusion layer.

3. A method of manufacturing a semiconductor device, comprising:
providing a semiconductor substrate of a first conductivity type;
forming a low impurity concentration diffusion layer of a second conductivity type in the semiconductor substrate, the second conductivity type being different from the first conductivity type;
forming a high impurity concentration diffusion layer of the second conductivity type in the low impurity concentration diffusion layer, the high impurity concentration diffusion layer being shallower than the low impurity concentration diffusion layer;
forming a silicide block layer over the semiconductor substrate;
removing selectively the silicide block layer that is on the high impurity concentration diffusion layer so that at least a portion of the high impurity concentration diffusion layer is exposed and the low impurity concentration diffusion layer is covered by the silicide block layer;
depositing a metal layer over the semiconductor substrate;
forming a metal silicide layer on the exposed high impurity concentration diffusion layer by transforming a portion of the metal layer in contact with the high impurity concentration diffusion layer into silicide by a heat treatment; and
removing the metal layer that has not been transformed into silicide.

4. The method of claim 3, wherein the silicide block layer comprises a silicon oxide film.

5. A method of manufacturing a semiconductor device, comprising:
providing a semiconductor substrate of a first conductivity type;
forming a low impurity concentration diffusion layer of a second conductivity type in the semiconductor substrate, the second conductivity type being different from the first conductivity type;
forming a high impurity concentration diffusion layer of the second conductivity type in the low impurity concentration diffusion layer, the high impurity concentration diffusion layer being shallower than the low impurity concentration diffusion layer;
forming a metal layer on a portion of the high impurity concentration diffusion layer so that the metal layer covers no part of the low impurity concentration diffusion layer; and
transforming the metal layer into a metal silicide layer by a heat treatment.
